(19) United States
(12) Patent Application Publication
(10) Pub. No.: US 2015/0309104 A1
(43) Pub. Date: Oct. 29, 2015

(54) DIFFERENTIAL CURRENT MONITORING DEVICE WITH ARC DETECTION

(71) Applicants: BENDER GMBH & CO. KG, Grûnberg (DE); ELLENBERGER & POENSGEN GMBH, Altdorf (DE)

(72) Inventors: Winfried MÖLL, Laubach (DE); Oliver SCHÄFER, Grünberg (DE); Harald SELLNER, Grünberg (DE); Bernd HÄUSLEIN, Nürnberg (DE); Michael KAMMER, Hungen (DE); Timm DECKER, Schwerte (DE); Christian STROBL, Burgthann (DE); Waldemar WEBER, Nürnberg (DE); Markus WIERSCH, Nürnberg (DE); Jürgen ZEBERL, Lauterhofen (DE)

(21) Appl. No.: 14/434,628

(22) PCT Filed: Sep. 20, 2013
(86) PCT No.: PCT/EP2013/069639

§ 371 Date: Apr. 9, 2015

(30) Foreign Application Priority Data
Oct. 11, 2012 (DE) 10 2012 218 504.6

(51) Int. Cl. G01R 31/02; G01R 15/18; H02H 3/08; G01R 17/02

(52) U.S. Cl. CPC G01R 31/025; G01R 17/02; G01R 15/183; H02H 3/08

(57) ABSTRACT

The invention relates to a differential current monitoring device for monitoring differential currents in power supply systems, having a first measuring current transformer and having a measuring circuit for determining the differential current and having a computing unit for evaluating the differential current and for generating a switch-off signal. The differential current monitoring device has a device for detecting arcs, the integration of which according to the invention can considerably reduce the technical effort needed to monitor the differential current in connection with the arc detection in comparison to a functionally and spatially separate arrangement of both protective measures.

The invention relates to a differential current monitoring device for monitoring differential currents in power supply systems, having a first measuring current transformer and having a measuring circuit for determining the differential current and having a computing unit for evaluating the differential current and for generating a switch-off signal.

Differential current monitoring devices are known as devices for galvanically isolated current measurement for electrical installations. A differential current monitoring device of this kind has the task of monitoring electrical installations or circuits for the occurrence of a differential current and to signal by an alarm if said differential current exceeds a predefined value. In contrast to residual current protective devices, differential current monitoring devices do not have a direct switch-off function themselves, but they can have a signal relay for transmitting alarm signals and, thus, they can indirectly cause a switch-off of the installation. For detecting a differential current, usually all active conductors of the line to be protected are guided as a primary winding through a measuring current transformer (core) that is provided with a secondary winding. In a fault-free power supply system, the vectorial sum of all currents—and thus the differential current—is zero so that no voltage is induced in the secondary winding. If, however, a fault current is running to ground, e.g., as a result of an insulation fault, then a differential current is flowing through the measuring current transformer. In case of a temporal change, the magnetic field of said differential current induces a voltage at the secondary side that can be detected and evaluated.

Aside from fault currents, undesired gas discharges (plasmas) can occur between the electrical conductors as other fault effects in electrical installations. Thus, early detection of these arc faults can help prevent damage to the installation and, in the worst case, prevent fires. For detection of an arc, it is known to monitor the (absolute) current of a conductor of the installation for fault components that are characteristically associated with an arc and can be determined by a spectral analysis of the current, for example. If a dangerous arc is detected, a signal is generated that switches off or short-circuits the installation so as to extinguish the arc.

The problem of arc detection becomes the center of attention in particular in connection with the installation of photovoltaic systems because special electrical protection requirements, e.g., with regard to fire protection, make a comprehensive electrical monitoring of the system necessary. According to legal regulations, differential current monitoring devices are integrated as part modules into the inverters of the photovoltaic system. Devices for arc detection, however, are not yet governed by a legal regulation of this kind, and according to the state of the art, if built in, they are separate units within an inverter or they are mounted separately as autonomous structural units. Thus, the realization of a comprehensive protective concept is relatively elaborate because of the large number of different protective devices.

Therefore, it is the object of the present invention to include a device for arc detection into the protective technology for the purpose of comprehensive electrical protection and to simplify the interaction of the arc detection device with known protective devices and to produce a product that is as cost-effective as possible with regard to economic aspects.

This object is attained in connection with the preamble of claim 1 in that the differential current monitoring device has a device for arc detection.

As, according to the invention, the device for arc detection is functionally integrated into the differential current monitoring device, the technical effort for monitoring the differential current combined with arc detection can be considerably reduced in comparison to a functionally and spatially separate arrangement of both protective measures. The circuitry-related integration of the device for arc detection allows a quick response time in the fault case by shared use of the same switch-off paths. Additionally, the functional and, depending on the design, also spatial combination of functional units for differential current detection with units for arc detection proves advantageous regarding costs in light of economic aspects, too. Substantial mechanical and electronic components do no longer have to be implemented in double. The use of “one” set of electronics thus considerably adds to cost reduction.

In the differential current monitoring device according to the invention, an evaluation of the absolute current may be additionally performed by means of the integrated arc detection in parallel to the monitoring for differential currents.

Moreover, the integrated arrangement allows that in case of simultaneous detection of a differential current and of an arc, a parallel arc to ground can be assumed, which, depending on the operational state of the electrical system, must not cause a switch-off.

In another advantageous embodiment, the device for arc detection has a second measuring current transformer, through which an active conductor of the power supply system is guided to register an individual conductor current, and a measuring circuit for determining the individual conductor current for the purpose of arc detection. Apart from the first measuring current transformer, which serves to determine the differential current in connection with the corresponding measuring circuit, the differential current monitoring device thus has a second measuring current transformer and another measuring circuit. The second measuring current transformer comprises an individual conductor so that the individual conductor current flowing in said conductor can be registered and determined in connection with a downstream measuring circuit.

Preferably, the arc detection measuring circuit for determining the individual conductor current is arranged in the differential current monitoring device, a computing unit for evaluating the individual conductor current differential current being combined with the computing unit for evaluating the differential current in a shared computing unit in the differential current monitoring device.

The arrangement of the arc detection measuring circuit in a shared housing with the differential current monitoring device leads to a compact structural design combined with a reduced assembly effort. A separate housing for accommodating the measuring circuit electronics for arc detection is no longer necessary. Also, additional hardware components can be used jointly and thus more effectively. For instance, one computer hardware can be used both for executing software programs to evaluate the differential current and for executing software programs to evaluate the individual conductor current.

In a particular embodiment, the second measuring current transformer for arc detection is arranged as an external current transformer in a spatially separate manner from the housing of the differential current monitoring device.

In this embodiment of the differential current monitoring device with integrated arc detection, only the measuring current transformer for registering the individual conductor current is arranged outside of a shared housing. The differential current and the individual conductor current are evaluated and determined centrally in a structural unit.

Preferably, the external second measuring current transformer for arc detection in a power supply system having a direct-voltage network, an inverter and an alternating-voltage network comprises an active conductor of the direct-voltage network.

In this embodiment, which can be advantageously employed in photovoltaic systems, the measuring current transformer for registering the differential current is arranged in the alternating-voltage network, whereas the second measuring current transformer for registering the absolute current for arc detection is installed in spatially separated manner thereof on the direct-voltage side of the photovoltaic system.

In this embodiment of the integrated differential current monitoring device, the first measuring current transformer for registering a differential current comprises all active conductors of a line to be protected of the alternating-voltage network. Since the first measuring current transformer is arranged on the alternating-voltage side and the second measuring current transformer is arranged on the direct-voltage side of the photovoltaic system, it is convenient to design the registration of the differential current in a conventional fashion in that one transformer core comprises all active conductors of the line to be monitored of the alternating-voltage network.

Furthermore, the shared computing unit of the differential current monitoring device generates a control signal to transfer the power supply system into a safe state. To be able to quickly extinguish an arc that has developed in the fault case, the shared computing unit in the extended differential current monitoring device generates a control signal that transfers the power supply system into a safe state by separation and/or short-circuiting and/or by changing the operating point of the electrical installation. For example, the control signal can be a signal for triggering the inverter that causes the latter to short-circuit the direct-voltage side of the photovoltaic system.

In an alternative embodiment, the first measuring current transformer and the second measuring current transformer are arranged one behind the other on the line to be monitored in such a manner that the first measuring current transformer for registering the differential current comprises all active conductors of the line to be monitored and the second measuring current transformer for arc detection comprises exactly one active conductor of the line to be monitored.

This embodiment is advantageous for monitoring a line of a 2-conductor or multi-conductor power supply system.

Preferably, in this context, the first measuring current transformer for registering the differential current and the second measuring current transformer for arc detection are realized as a combined double transformer.

This sort of structural design as a double transformer requires little structural space and is, therefore, particularly advantageous in confined installation environments.

In another embodiment, the first measuring current transformer for registering the differential current and the second measuring current transformer for arc detection are arranged in a shared housing of the differential current monitoring device.

Both in the realization as separate transformers and in the realization as a double transformer, the measuring current transformers can be integrated in a shared housing. Thus, the differential current monitoring device with integrated arc detection can be designed even more compactly with simultaneously reduced installation effort.

Another embodiment having at least two measuring current transformers is designed such that each active conductor of the line to be monitored in a 2-conductor or multi-conductor power supply system is guided through one respective measuring current transformer and at least one measuring current transformer has two secondary windings, the respective first windings being used for differential current monitoring and the second windings being used for arc monitoring.

In this version of the differential current monitoring device, the differential current registration does not take place conventionally by means of only one transformer core that comprises all active conductors of the line to be monitored, but in that each active conductor is guided through its own measuring current transformer. The differential current measurement and the arc detection as well as a potentially implemented load current measurement are all based on the registration of the individual conductor currents. In this context, the respective first windings of a measuring current transformer are used to determine the differential current, and the respective second windings are used for arc detection.

Preferably, the differential current is determined computationally by a logic operation of the measuring signals generated by the measuring current transformers.

The differential current can be calculated from the evaluable measuring signals generated by the individual measuring current transformers in connection with the associated measuring circuits based on a vectorial addition of the measuring signals.

In another embodiment, the differential current monitoring device has means for determining a load current. The presence of measuring current transformers in each individual line can advantageously be used for load current measurements. Similar to the differential current measurement and the detection of an arc, the determination of the load current is based on the currents in the individual lines that are registered by the measuring current transformers.

Furthermore, the underlying object is attained, in particular in highly branched power supply systems, by an apparatus for differential current monitoring that combines multiple differential current monitoring devices according to any of the claims 1 to 13 in a structural unit for multi-channel monitoring of differential currents and for multi-channel arc detection. For example, if a power supply system with multiple outgoing power feeds is to be monitored with regard to occurring differential currents and for the occurrence of an arc, multiple differential current monitoring devices according to the invention can advantageously be integrated in one structural unit. This offers advantages because shared constructive, in particular electronic, resources such as components of the power supply or the processor capacity can be used effectively.

Other advantageous embodiment features become apparent from the following description and the drawings, which illustrate preferred embodiments of the invention with the aid of examples. In the figures:

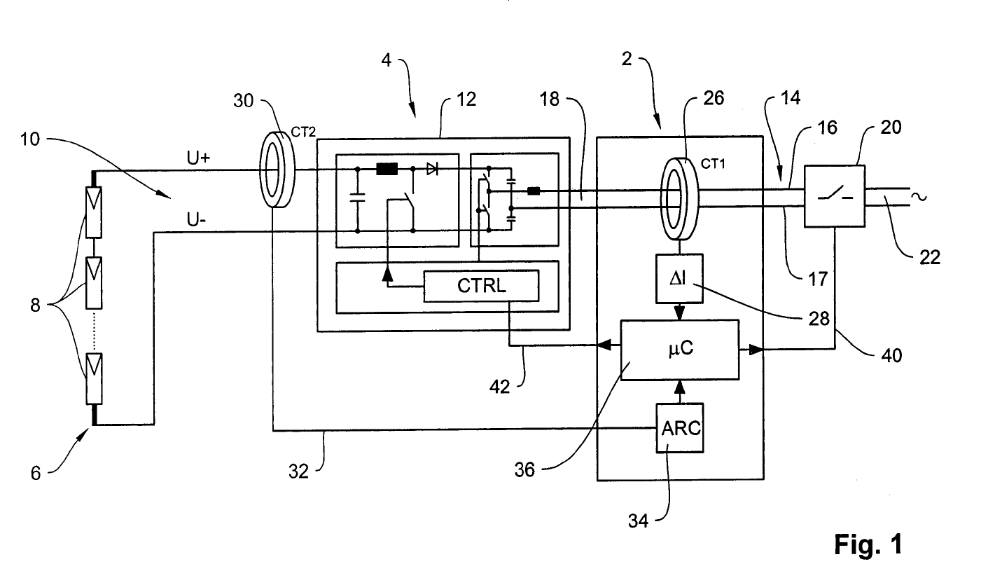

FIG. 1: shows a first embodiment of a differential current monitoring device for a photovoltaic system,

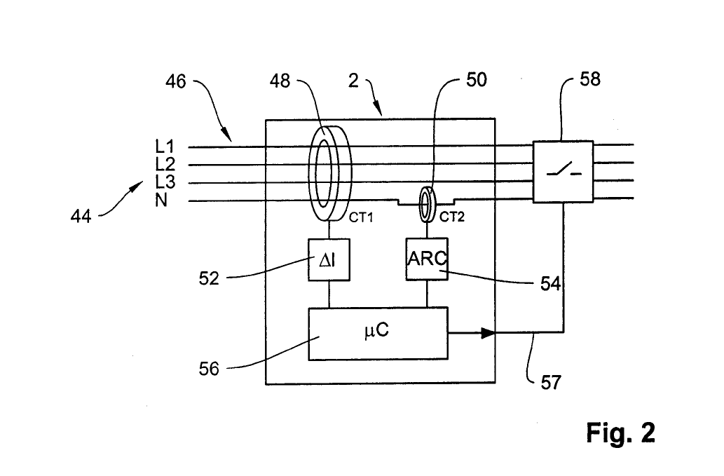

FIG. 2: shows a second embodiment having an integrated second measuring current transformer for arc detection,

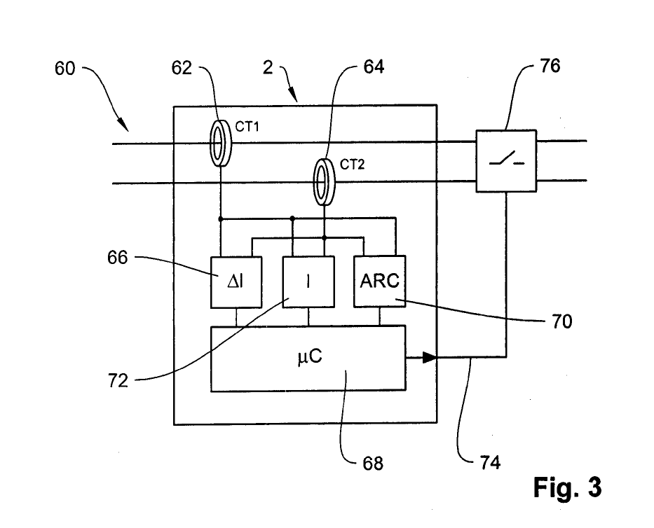

FIG. 3: shows a third embodiment having measuring current transformers for each individual conductor.

FIG. 1 schematically shows a simplified illustration of a differential current monitoring device 2 according to the invention in connection with the monitoring of a photovoltaic system 4. On the generator side, said photovoltaic system 4 is symbolized by a string 6 of solar energy modules 8 that generates a direct-voltage network 10 having the photovoltaic direct voltages U+ and U−.

The photovoltaic voltages U+ and U− generated in case of sufficient irradiation of the solar energy modules 8 are fed to an inverter 12. In the illustrated example, said inverter 12 generates an alternating-voltage network 14 at the output side, said alternating-voltage network 14 having a line 18 that is composed of two active conductors 16, 17 and is coupled to an external power supply network 22 via a switch-off device 20.

The differential current monitoring device 2 according to the invention has a first measuring current transformer 26 having a measuring circuit 28 for registering and determining a differential current occurring in the line 18. All active conductors 16, 17 of the line 18 to be monitored are guided through the measuring current transformer 26.

A second measuring current transformer 30 for arc detection is arranged as an external current transformer in a spatially separate manner from the housing of the differential current monitoring device 2 on the direct-voltage side of the photovoltaic system where it surrounds an active conductor of the direct-voltage network 10. The second measuring current transformer 30 is connected via a connecting line 32 (remote CT connection, CT current transformer) to a measuring circuit 34 for determining the absolute current running in the active conductor of the direct-voltage network 10 to the differential current monitoring device 2. The differential current and the absolute current are evaluated in a shared computing unit 36 of the differential current monitoring device 2. If a response value of the differential current is exceeded or if a current distortion is recognized that indicates the development of an arc, a switch-off signal 40 is generated that separates the photovoltaic system 4 from the external power supply network 22 by means of the switch-off device 20. Further, a control line 42 is provided that leads from the shared computing unit 36 of the differential current monitoring device 2 to the inverter 12, which short-circuits the photovoltaic system 4 in the fault case so as to extinguish the arc.

In FIG. 2, a second embodiment of the differential current monitoring device 2 is schematically illustrated. The differential current monitoring device 2 according to the invention is installed in a line 44 of an alternating-current network 46, said line being composed of four active conductors L1, L2, L3 and N, and has a first measuring current transformer 48 and a second measuring current transformer 50 that are arranged one behind the other on the line 44 to be protected in such a manner that the first measuring current transformer 48 for registering the differential current comprises all active conductors L1, L2, L3 and N of the line 44 to be protected and the second measuring current transformer 50 for arc detection comprises exactly one active conductor of the line 44 to be protected, in this case conductor N, for example. As in the first embodiment according to FIG. 1, the first measuring current transformer 48, in connection with a measuring circuit 52, provides an evaluable measuring signal for determining the differential current, and the second measuring current transformer 50, in connection with a measuring circuit 54, provides an evaluable signal for determining the absolute current in an active conductor. Both measuring signals are evaluated in the shared computing unit 56, and they cause a switch-off of the installation in the fault case by generating of a switch-off signal 57 for a switch-off device 58.

The two measuring current transformers 48, 50 are preferably arranged in a shared housing with the measuring circuits 52, 54 and the shared computing unit 56. Moreover, the measuring current transformers 48, 50 can be realized as separate transformers or as a combined double transformer.

The third embodiment, illustrated in FIG. 3, schematically shows the installation of the differential current monitoring device 2 according to the invention in a 2-conductor power supply system 60. The differential current monitoring device 2 has two measuring current transformers 62 and 64 that each comprise one active conductor of the power supply system 60. Both measuring current transformers 62, 64 have a first secondary winding via which the differential current is computationally determined in a shared computing unit 68 in connection with a measuring circuit 66 for determining the differential current. At least one of the two measuring current transformers 62, 64 has a second secondary winding that is used in connection with a measuring circuit 70 to determine the absolute current for the purpose of arc detection. Moreover, the integrated differential current monitoring device 2 has means 72 for load current calculation and, analogously to the first end second embodiment, it also offer the possibility of generating a switch-off signal 74 in the shared computing unit 68 in the fault case, said switch-off signal 74 causing a switch-off of the power supply system 60 from an external network by means of a switch-off device 76.

1. A differential current monitoring device (2) for monitoring differential currents in power supply systems (4, 10, 14, 46, 60), having a first measuring current transformer (26, 48, 62) and having a measuring circuit (28, 52, 66) for determining the differential current and having a computing unit for evaluating the differential current and for generating a switch-off signal (40, 57, 74),
characterized by
a device for arc detection.

2. The differential current monitoring device according to claim 1,
characterized in that
the device for arc detection has a second measuring current transformer (30, 50, 64) through which an active conductor of the power supply system is guided for registering an individual conductor current, and a measuring circuit (34, 54, 70) for determining the individual conductor current for the purpose of arc detection.

3. The differential current monitoring device according to claim 2,
characterized in that
the arc detection measuring circuit (34, 54, 70) for determining the individual conductor current for the purpose of arc detection is arranged in the differential current monitoring device (2) and a computing unit for evaluating the individual conductor current is combined with the computing unit for evaluating the differential current in a shared computing unit (36, 56, 68) in the differential current monitoring device (2).

4. The differential current monitoring device according to claim 2,
characterized in that
the second measuring current transformer (30) for arc detection is arranged as an external current transformer in a spatially separate manner from the housing of the differential current monitoring device (2).

5. The differential current monitoring device according to claim 4,
characterized in that
the external second measuring current transformer (30) for arc detection in a power supply system (4, 10, 14, 46, 60) having a direct-voltage network (10), an inverter (12) and an alternating-voltage network (14) comprises an active conductor of the direct-voltage network (10).

6. The differential current monitoring device according to claim 5,
characterized in that
the first measuring current transformer (26) for detecting a differential current comprises all active conductors (16, 17) of the alternating-voltage network (14).

7. The differential current monitoring device according to claim 5,
characterized in that
the shared computing unit (36, 56, 68) of the differential current monitoring device (2) generates a control signal to transfer the power supply system (4, 10, 14, 46, 60) into a safe state.

8. The differential current monitoring device according to claim 2,
characterized in that
the first measuring current transformer (48) and the second measuring current transformer (50) are arranged one behind the other on the line (44) to be monitored in such a manner that the first measuring current transformer (48) for registering the differential current comprises all active conductors of the line (44) to be monitored and the second measuring current transformer (50) for arc detection comprises exactly one active conductor of the line (44) to be monitored.

9. The differential current monitoring device according to claim 8,
characterized in that
the first measuring current transformer (48) for registering the differential current and the second measuring current transformer (50) for arc detection are realized as a combined double transformer.

10. The differential current monitoring device according to claim 8,
characterized in that
the first measuring current transformer (48) for registering the differential current and the second measuring current transformer (50) for arc detection are arranged in a shared housing of the differential current monitoring device (2).

11. The differential current monitoring device according to according to claim 1,
characterized by
at least two measuring current transformers (62, 64) in such a fashion that in a 2-conductor or multiple-conductor power supply system (60) each active conductor of the line to be monitored is guided through one respective measuring current transformer (62, 64) and at least one measuring current transformer (62, 64) has two secondary windings, the respective first windings being used for differential current monitoring and the second windings being used for arc monitoring.

12. The differential current monitoring device according to claim 11,
characterized in that
the differential current is determined computationally by a logic operation of the measuring signals generated by the measuring current transformers (62, 64).

13. The differential current monitoring device according to claim 11,
characterized by
means (72) for determining a load current.

14. An apparatus for differential current monitoring,
characterized by
an integration of multiple differential current monitoring devices according to claim 1 in a structural unit for multi-channel monitoring of differential currents and for multi-channel arc detection.
